(19) United States
(12) Patent Application Publication
(10) Pub. No.: US 2013/0192065 A1
(43) Pub. Date: Aug. 1, 2013

(54) METHOD FOR MANUFACTURING A CIRCUIT

(71) Applicants: Ayad Ghannam, Toulouse (FR); David Bourrier, Toulouse (FR); Monique Dilhan, Plaisance (FR); Christophe Viallon, Toulouse (FR); Thierry Parra, Toulouse (FR)

(72) Inventors: Ayad Ghannam, Toulouse (FR); David Bourrier, Toulouse (FR); Monique Dilhan, Plaisance (FR); Christophe Viallon, Toulouse (FR); Thierry Parra, Toulouse (FR)

(73) Assignee: Centre National De La Recherche Scientifique (C.N. R.S.), Paris (FR)

(21) Appl. No.: 13/877,482

(22) PCT Filed: Oct. 5, 2011
(86) PCT No.: PCT/FR2011/052325

§ 371 Date: Apr. 3, 2013

(30) Foreign Application Priority Data
Oct. 5, 2010 (FR) 10 58076

(51) Int. Cl. H05K 3/30

(52) U.S. Cl. CPC H05K 3/30
USPC 29/846

(57) ABSTRACT

A method for manufacturing an integrated circuit includes the steps of: forming above an upper surface of a substrate (5) at least one dielectric layer (15) extending on an underlying surface (12), the dielectric layer (15) having an upper surface (25) and a flank (40) extending between the upper surface and the underlying surface (12); and forming an electrical structure (70) in one piece in an electrically conducting material including a structural element (75) extending on the upper surface (25) of the dielectric layer (15) and an interconnection element (80) extending from the structural element (75) along the flank (40) as far as the underlying surface. The flank has a height of more than 10 μm, and the electrical structure is formed by depositing the electrically conducting material by simultaneously depositing the structural element on the upper surface of the dielectric layer and the interconnection element on the flank.

The present invention relates to a method for manufacturing an integrated circuit, of the type comprising the steps of:

forming above an upper surface of a substrate, at least one dielectric layer extending on an underlying surface, the dielectric layer having an upper surface and a flank extending between the upper surface and the underlying surface; and

forming an electric structure in one piece in an electrically conducting material, comprising a structural element extending on the upper surface of the dielectric layer and an interconnection element extending from the structural element along the flank as far as the underlying surface.

### FIELD OF THE INVENTION

The present development of mobile telecommunications is accompanied by a constantly increasing demand for more and more performing new technologies, low costs and reliability for producing high frequency and miniaturized electronic circuits. In this context, the superiority of monolithic technologies seems indisputable if they are compared with hybrid technologies which consist of assembling by welding discrete electronic components.

These technologies are applied by a smelter, which generally does not allow access to the technological method. In this case, it is then possible to form passive electronic components or interconnection lines above the substrate containing the active components, by means of a compatible complementary method. This type of integration is called <<above-IC>> integration.

For certain applications (such as for example RF and microwave power amplification, RF passive filtering, transfer and interconnections of chips, the integration of antennas on chips . . . ) it is necessary to have a method giving the possibility of making passive components and interconnections having good electrical performances and insensitive to the dielectric quality of the substrate. This point is particularly critical in the case of applications on silicon since, as the technological procedures are generally accompanied by not very resistive substrates, the passive components have significant losses. In particular, in the case when the passive components formed on the substrate are inductors, the low resistivity of the substrate leads to a poor quality factor for these inductors. Also, in order to further increase the quality factor of the components, or to reduce their level of losses, it is necessary to implement metal levels with a large thickness.

### STATE OF THE ART

In order to limit the interactions between the substrate and the passive electronic components for which great quality is desired, it is possible to screen the substrate by means of a metal plane and to form on this screen, thick layers of insulating material on which these passive components are made. In order to connect the components, for example active components, possibly integrated at the surface of the substrate, and passive components formed above this substrate on the thick layer of insulating material, it is necessary to make metallized interconnection apertures entirely crossing the thick dielectric layer. As mentioned earlier, the components should also be formed from metal levels of sufficient thickness.

For this purpose, a method may be used consisting of successively:

a—depositing an adhesion layer, forming an electrolytic growth base on the upper surface of the substrate;

b—depositing on this adhesion layer, a thick layer of resin in which apertures are made by photolithography only in the areas in which it is desired to form the first portion of the electrical structure. This first portion of the structure will form interconnection elements making the electric interconnection between the components integrated at the surface of the semi-conducting substrate and the components which will be formed at the surface of the thick insulating material;

c—growing in the apertures made in the resin, the interconnection element(s) by electrolytic deposition of a conducting material, from the adhesion layer;

d—removing the resin layer;

e—etching the adhesion layer in the areas in which it is not covered by the first portion of the electrical structure;

f—depositing around the first portion of the electrical structure, a dielectric layer by spin coating;

g—polishing the upper surface of the dielectric layer;

The polishing of the upper surface of the dielectric layer is necessary since the presence of the first portion of the electrical structure within the dielectric layer generates thickness irregularities of this layer during its spin coating.

At the end of this step, a dielectric layer was formed on the substrate and the interconnection elements were formed through this dielectric layer;

h—A structural element extending on the dielectric layer and forming an interconnection level is then formed. For this purpose, a new metal adhesion layer and then a structured resin layer on this adhesion layer are successively deposited on the dielectric layer before proceeding with electrolytic deposition of the interconnection level;

i—the resin is dissolved,

j—the adhesion layer is etched.

For each additional level of interconnections, it is generally necessary to repeat the steps a- up to j-, one alternative consisting of not carrying out step j- and resuming from step b-.

Thus, a large number of technological steps are necessary for obtaining a passive electrical structure, comprising one or several interconnection levels when one or several insulating dielectric layers of significant thicknesses are deposited on the integrated circuit.

The object of the present invention is to propose a manufacturing method similar to the method described earlier but for which the number of technological steps is strongly reduced.

### DISCUSSION OF THE INVENTION

For this purpose, the object of the invention is a method for manufacturing an integrated circuit of the aforementioned type, in which the flank has a height of more than 10 μm, and the electrical structure is formed by depositing the electrically conducting material by simultaneously depositing the structural element on the upper surface of the dielectric layer and the interconnection element on the flank.

The method according to the invention may comprise one or more of the following features taken individually or according to all technically possible combination(s):

the or each dielectric layer is in polymeric material;

the flank of the dielectric layer is undercut relatively to the upper surface of the substrate or normal to the upper surface of the substrate;

the step of forming the electrical structure successively comprises:
the deposition of a first metallization coating on the underlying lower layer and on the upper surface of the or each dielectric layer;
the deposition of a second metallization coating on the flank of the or each dielectric layer; and
the deposition of the electrical structure by electrolytic growth simultaneously on the first metallization coating and on the second metallization coating.

the deposition of the second metallization coating is carried out by chemical treatment of the flank of the dielectric layer.

the step of forming the electrical structure comprises, after the depositions of the first and second metallization coatings, the deposition of a resin layer leaving exposed the regions of the first metallization coating, intended to be covered with the electrical structure during the electrolytic deposition step, and the removal of the resin layer after the electrolytic deposition.

at least one dielectric layer is provided with an interconnection through-aperture delimited by the flank;

several superposed dielectric layers defining a stepped dielectric structure are formed on the underlying surface, each dielectric layer having an upper surface and a flank extending between its upper surface and the upper surface of an underlying dielectric layer or the underlying surface, at least one of the flanks having a height of more than 10 μm, and the electrical structure is formed by simultaneously depositing a structural element extending on the upper surface of each dielectric layer and an interconnection element extending along the flank of each dielectric layer from the structural element extending on the upper surface of this dielectric layer as far as the upper surface of the underlying dielectric layer or as far as the underlying surface.

the flank of each dielectric layer has a thickness of more than 10 μm.

each dielectric layer is in polymeric material.

the electric structure is formed by electrolytic deposition.

With the invention it is possible to apply an <<above IC>> low temperature method based on the deposition of a thick polymeric dielectric (for example up to 140 μm) in which metallized holes are made for the electric connections with the active chip. The metallizations are made at the surface of this dielectric by electrolytic growth (up to a thickness of 35 μm). The advantages of the method notably lie in the structuration of the polymer, in order to limit the mechanical stresses undergone by the host substrate, as well as in the growth of the metal in a single step, for filling the metallized holes and for making interconnections and inductors at the surface of the polymer. Indeed, this method makes it possible to manufacture in a single step continuous metal lines capable of stretching over dielectric flanks which are vertical and of significant heights. With this same method, a connection line may be integrated on several thick dielectric levels in a single metal growing step. Finally, this method may be used for integrating several interconnection levels. In each case, the final chip is more robust mechanically and, by removing a large number of interfaces between metal levels, the electrical performances of the structures are improved.

The invention also relates to an integrated circuit obtained according to a method of the invention.

Thus, it generally relates to an integrated circuit comprising a substrate having an upper surface, at least one dielectric layer formed above the upper face of the substrate and extending on an underlying surface, the dielectric layer having an upper surface and a flank extending between the upper surface and the underlying surface, an electrical structure made in one piece in an electrically conducting material, comprising a structural element extending on the upper face of the dielectric layer and an interconnection element extending from the structural element along the flank as far as the underlying surface, in which the flank has a height of more than 10 μm, and the dielectric structure is deposited on the upper surface and the flank of the dielectric layer.

The electrical structure results from a deposit, notably from an electrolytic deposit, on the underlying surface and the upper surface of the dielectric layer covered with a first metallization coating, notably resulting from deposition by cathodic sputtering or by thermal evaporation, and on the flank covered with a second metallization coating, notably resulting from chemical treatment of the flank.

### SHORT DESCRIPTION OF THE FIGURES

The invention will be better understood upon reading the description as follows, only given as an example and made with reference to the appended drawings, wherein:

FIGS. 1 to 7 are schematic cross-sectional views illustrating the successive steps of the method for manufacturing an integrated circuit according to a first embodiment of the invention, resulting in an electrical structure with one level;

FIG. 8 is a photograph of a portion of the integrated circuit of FIG. 7, more particularly illustrating the formed electrical structure;

FIG. 9 is a schematic sectional view similar to FIG. 7 of an integrated circuit obtained by a method for manufacturing an integrated circuit according to a second embodiment;

FIGS. 10 to 17 are schematic cross-sectional views illustrating the successive steps of the method for manufacturing an integrated circuit according to a third embodiment, resulting in an electrical structure with two levels;

FIG. 18 is a photograph of a cross-section of a portion of the integrated circuit of FIG. 17;

FIG. 19 is a photograph of an integrated circuit obtained by the manufacturing method according to the third embodiment;

FIG. 20 is a schematic sectional view illustrating a circuit according to one alternative; and

FIG. 21 is a schematic sectional view illustrating a circuit according to another alternative.

### DETAILED DESCRIPTION OF THE INVENTION

The method according to the invention allows integration of passive electrical structures on a substrate, notably above an active or conducting area of this substrate. This substrate is for example made in a semi-conducting material. These passive electrical structures are in particular passive electronic components, such as inductors, capacitors, resistors, antennas or interconnections. Such interconnections are notably intended for establishing electric connections between various regions of an active or conducting area of the substrate, between various active or conducting areas of the substrate or between active or conducting areas of several stacked integrated circuits. They may also form interconnection elements able to allow electric connections of a discrete electronic component, i.e. not integrated to the monolithic circuit.

In the following of the description, the terms of <<lower>> and <<upper>> are used with reference to the substrate, the term of <<lower>> designating the portion of an element which is the closest to the substrate and the term of <<upper>> designating the portion of this element which is the farthest from the substrate.

### First Embodiment

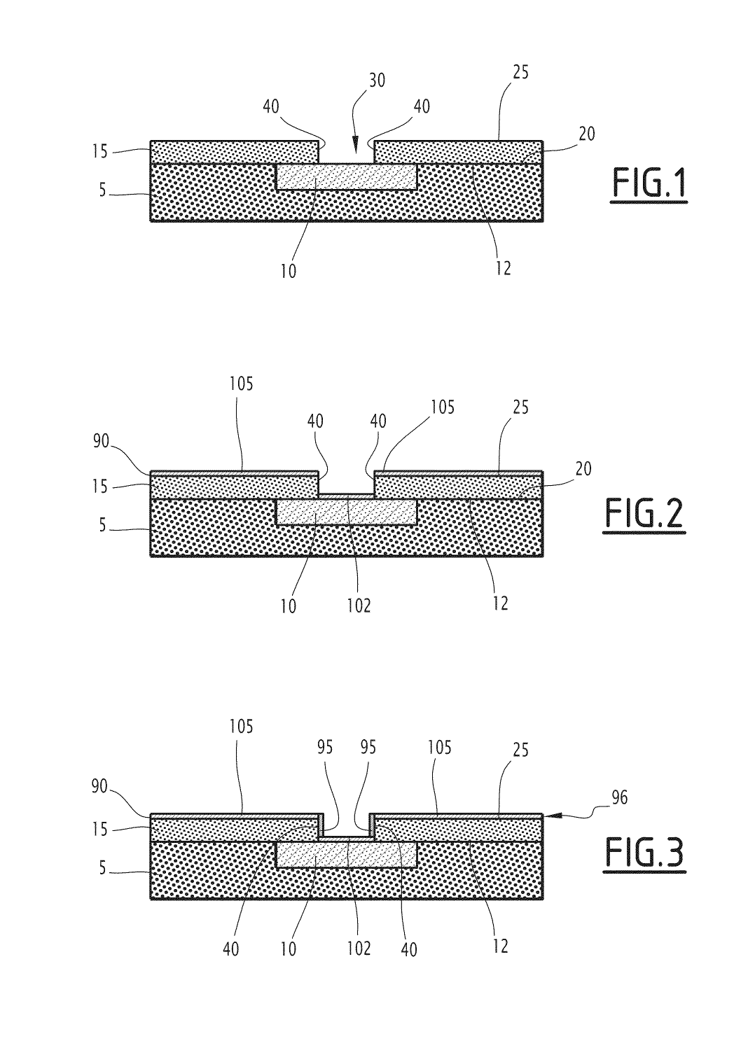

FIGS. 1 to 7 illustrate the successive steps of the method for manufacturing a monolithic integrated circuit according to a first embodiment of the invention.

The method is carried out on a substrate 5 made in a semi-conducting material. The substrate 5 is in particular made in silicon. Alternatively, it is a glass substrate or a flexible substrate (for example made in PET, polyimide . . . ). According to another alternative, the substrate is made in epoxy resin or from polychlorobiphenyl (PCB).

It appears as a wafer with a thickness comprised for example between 200 μm and 1.5 mm. The substrate 5 comprises a substantially planar upper surface 12.

In the illustrated embodiment, the substrate 5 comprises at least one active or conducting area 10 on which it is desired to make a connection. The area 10 is an active area, i.e. an area of the substrate into which has been integrated an active electronic component, such as a diode or a transistor, or simply a conducting area. The area 10 is in particular the electrode of an active electronic component, such as a transistor or a diode. The area 10 was integrated beforehand into the substrate by any method known to one skilled in the art.

In a first step, a dielectric layer 15 is formed on the upper surface 12 of the substrate 5. The dielectric layer 15 comprises a lower surface 20, an upper surface 25 and an interconnection aperture 30 crossing the dielectric layer 15. The interconnection aperture 30 is delimited by two facing flanks 40 of the dielectric layer 15. It is positioned in register with the area 10 and opens into the latter. Each flank 40 of the dielectric layer 15 is substantially normal to the upper surface 12 of the substrate 5. In this context, a dielectric layer is an electrically insulating layer.

According to an alternative, each flank 40 is undercut relatively to the upper surface 12 of the substrate 5. In this case, the facing flanks 40 converge towards each other away from the substrate 5.

According to alternatives, intermediate layers, in particular metal layers are inserted between the upper surface 12 of the substrate 5 and the dielectric layer 15. In this case, the dielectric layer 15 extends over an underlying lower layer and each of its flanks 40 extends between its upper surface 25 and an upper surface of the underlying lower layer.

The dielectric layer 15 is made in a polymeric material, capable of allowing formation of layers with significant thickness. The polymeric material is in particular with a thickness of more than 10 μm, notably more than 25 μm, in particular more than 80 μm, and even most particularly more than 100 μm. In the illustrated embodiment, the dielectric constant of the polymeric material is 2.85. The polymeric material used is capable of polymerizing under the effect of insolation, and there exists a developer capable of selectively removing the non-polymerized polymeric material. The polymeric material is advantageously Su-8 resin, or a polyimide such as Kapton®, Durimide® or Intervia®.

In order to form the dielectric layer 15, the dielectric polymeric material is coated onto the upper surface 12 of the substrate 5 so as to obtain a full plate layer of dielectric polymeric material. By full plate layer is meant a layer entirely covering the upper surface 12 of the substrate 5. The thereby obtained full plate layer is then structured by selectively removing the dielectric material in certain regions by photolithography so as to obtain the dielectric layer 15 having the desired structure. In the embodiment illustrated in FIGS. 1 to 8, the structuration consists of opening by photolithography the aperture(s) 30 in the full plate layer, so as to form the dielectric layer 15 provided with the apertures 30 (FIG. 1).

The dielectric layer 15 has a significant thickness, taken between its lower surface 20 and its upper surface 25, notably a thickness of more than 10 μm, more particularly of more than 25 μm, even most particularly more than 80 μm, and even most particularly more than 100 μm. In the embodiment illustrated in FIGS. 1 to 8, the dielectric layer 15 has a thickness of about 70 μm.

An electrical structure 70 made in one piece of material, comprising a structural element 75 extending on the upper surface 25 of the dielectric layer 15 and an interconnection element 80 extending from the structural element 75 through the interconnection aperture 30 along the flanks 40 of the first dielectric layer 15 and as far as the upper surface 12 of the substrate 5 is then formed. The interconnection element 80 therefore extends over the whole height of the flanks 40. It electrically connects the structural element 75 to the area 10.

In the case (not shown) when intermediate layers are inserted between the upper surface 12 of the substrate 5 and the dielectric layer 15, the interconnection element 80 extends from the structural element 75 along the flanks 40 as far as the upper surface of the underlying lower layer. It then electrically connects the structural element 75 to the underlying layer, which is for example an electrical interconnection layer.

The step of forming the electrical structure 70 successively comprises:

the deposition of a first metallization coating 90 (FIG. 2),

the deposition of a second metallization coating 95 (FIG. 3), the first and the second metallization coating 90, 95 forming together a continuous, electrically conducting base for electrically conducting, continuous electrolytic growth 96;

the deposition of a resin layer 100 (FIG. 4);

the deposition by electrolytic growth of the electrical structure 70 (FIG. 5);

the removal of the resin layer 100 (FIG. 6); and

the etching of the first metallization coating 90 in the regions in which it is not covered with the electrical structure 70 (FIG. 7).

Thus, in order to form the electrical structure 70, the first metallization coating 90 is deposited on the exposed upper surfaces, i.e. in particular on the upper surface 25 of the dielectric layer 15 and on the upper surface 12 of the substrate 5 through the interconnection aperture 30. The first metallization coating 90 comprises a first portion 102 covering the upper surface 12 of the substrate 5 and a second portion 105 extending on the upper surface 25 of the dielectric layer 15.

It is made in a metal material, in particular in an electrically conducting material, capable of forming an adhesion layer and of promoting adhesion of the material forming the electrical structure 70 by electrolytical growth. The first metallization coating 90 is in particular made by successive deposition of two layers. The first layer is an adhesion base for example made in titanium, chromium or in a titanium/tungsten alloy . . . Alternatively, the adhesion base is made in tantalum or tungsten. The second layer is a base for growing the electrolytic deposit for example made in gold, copper or nickel.

The first metallization coating 90 is a thin layer with a thickness of the order of 0.25 μm.

The first metallization coating 90 is deposited with a conventional method for depositing a metal material, known to one skilled in the art, in particular by cathodic sputtering or by thermal evaporation. During such a deposition, the exposed upper surfaces are easily reached by the metal material forming the first coating 90, and these surfaces are thus covered continuously. On the other hand, due to the significant thickness of the dielectric layer 15 and to the geometry of the flanks 40, conventional methods for depositing a metal coating do not allow proper covering of the flanks 40 with the metal material.

In order to form the base for continuous electrolytic growth 96, the second metallization coating 95 is deposited (FIG. 3) on the flanks 40 of each interconnection aperture 30. The second metallization coating 95 thus forms an electrical connection between the first portion 102 and the second portion 105 of the first metallization coating 90.

Considering the topology of the flanks 40, which are normal to the upper surface 12 or undercut, the second metallization coating 95 is deposited by chemical treatment of the flanks 40, or <<metallization by chemical deposition>>. This chemical treatment of the flanks 40 of the dielectric layer 15 in particular comprises:

the preparation of the flanks 40, consisting in their cleaning in order to clear them from residues which may possibly be prejudicial during the following steps of the chemical treatment;

the deposition on the thereby prepared flanks 40 of an initiator promoting adherence of the ions of the metal (palladium) forming the metallization coating 95 and allowing catalysis of these metal ions so as to form the second metallization coating 95 and thus making the flanks 40 conducting.

Each of these phases is achieved by immersion into a bath containing a suitable solution.

The second metallization coating 95 is for example formed using the optimized Envision® method from Cookson Electronics.

The second metallization coating 95 is made in a material having properties similar to the material of the first metallization coating 90.

The resin layer 100 is then deposited (FIG. 4) on the first metallization coating 90 so as to cover the regions of this coating 90 which are not intended to be put into contact with the electrical structure 70, and to leave exposed the regions of the first metallization coating 90 intended to be put into contact with the electrical structure 70. A mold is thereby formed for depositing the electrical structure 70, capable of limiting the extension of the electrically conducting material during the electrolytic deposition step, the electrically conducting material not being able to be deposited on the areas of the first metallization coating 90 covered with the resin layer 100.

Thus, in the first embodiment, the resin layer 100 covers areas of the second portion 105 of the first metallization coating 90, i.e. areas of the first metallization coating 90 in register with the first dielectric layer 15.

The resin layer 100 having the desired structure is obtained by any suitable method known to one skilled in the art, in particular by photolithography. The resin layer 100 has significant thickness, in particular a thickness comprised between 10 μm and 200 μm. In the illustrated example, it has a thickness about equal to 90 μm.

The resin forming the resin layer 100 is in particular a photosensitive resin of the negative type having a resolution of 1 for 10, i.e. that the smallest width of the trenches which may be obtained by photolithography from a resin layer with a thickness about equal to 100 μm is 10 μm. It is thus possible to form patterns with a width greater than or equal to 10 μm for a resin thickness of 100 μm.

The electrical structure 70 is then formed (FIG. 5) by simultaneously depositing with an electrolytic deposition method, the electrically conducting material on the areas of the continuous electrolytic growth base 96 not covered with the resin layer 100. Because of its continuity, the electrolytic growth base 96 is able to conduct an electrolytic current over the whole of its surface, to thereby allow simultaneous formation and in one piece of the interconnection element 80 and of the structural element 75 by simultaneous deposition of the electrically conducting material on an area of the upper surface 12 of the substrate 5 delimited by the interconnection aperture 30, on the upper surface 25 of the dielectric layer 15, and on the flanks 40 during electrolytic growth of the electrically conducting material.

Thus, in the embodiment illustrated in FIGS. 1 to 8, the electrically conducting material is deposited simultaneously over the upper surface 12 of the substrate 5 through the interconnection aperture 30, on the upper face 25 of the dielectric layer 15, and on the flanks 40 so as to simultaneously form the first structural element 75 and the interconnection element 80.

The electrical structure 70 made in one piece of material is thus formed in a single electrolytic growth step.

The electrical structure 70 is made in an electrically conducting material and capable of being deposited by electrolysis. It is advantageously made in copper. Alternatively, it is made in gold or in metal alloys allowing electrolytic deposition. The structural element 75 for example forms all or part of an electronic component, notably of a passive electronic component such as an inductor. It may also form an interconnection line, intended to connect together various regions of the area 10.

The thickness of the structural element 75 depends on its electronic function. It also depends on the application of the circuit. As an example, structural elements will be provided with larger thicknesses in a power amplifier circuit than those which will be necessary for structural elements of a low level or low noise amplifier circuit. As an indication, the thickness of a structural element 75 is for example comprised between 5 μm and 150 μm. More particularly, the thickness of a structural element 75 is for example comprised between 5 and 200 μm.

After having formed the electrical structure 70, the resin layer 100 is dissolved (FIG. 6), for example by immersion of the assembly illustrated in FIG. 5 in a bath capable of selectively dissolving the resin layer 100.

Finally, the continuous electrolytic growth base 96 is etched (FIG. 7) in the areas in which it is not covered with the electrical structure 70, i.e. in the areas which were before covered with the resin layer 100. This etching is carried out by any suitable etching method, notably by chemical etching.

A monolithic integrated circuit 126 as illustrated in FIG. 7 and comprising one interconnection level formed by the structural element 75 is thereby obtained.

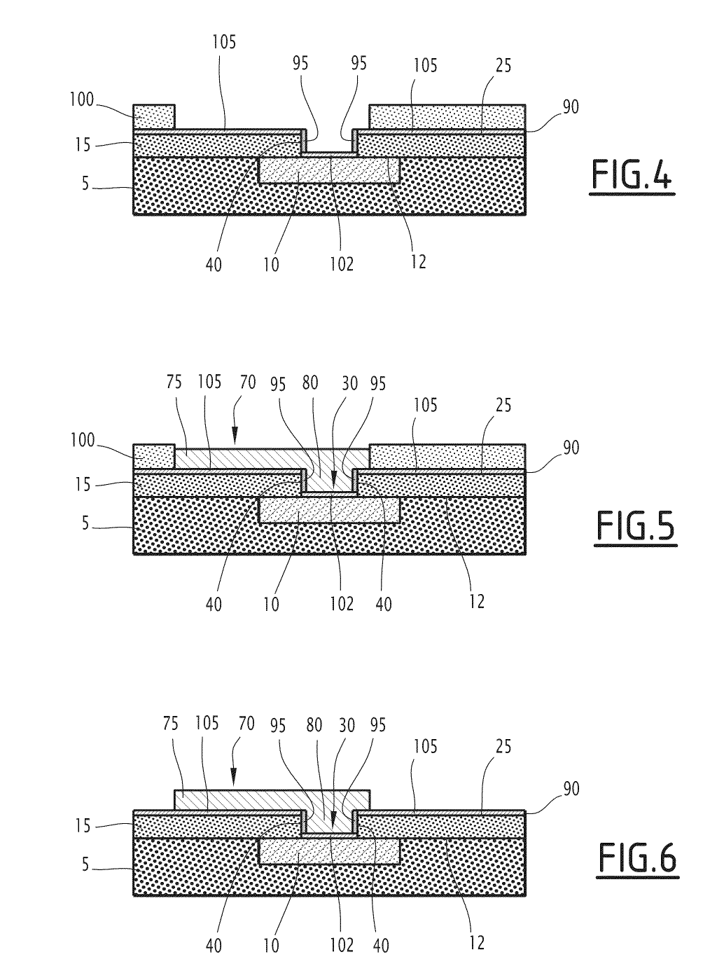

FIG. 8 is a photograph representing a portion of the monolithic integrated circuit 126 obtained by the method according to the first embodiment, and more particularly showing the electrical structure 70 made in one piece of material formed above the area 10.

As an option, during its formation, the dielectric layer 15 is structured so as to only cover a limited area of the upper surface 12 of the substrate 5. The formation of a dielectric layer 15 only extending on a limited region of the upper surface of the substrate 5 or of an underlying layer, is advantageous. Indeed, the dielectric material tends to retract during polymerization, which causes significant mechanical stresses on the substrate 5, which, because of its small thickness, is very fragile. The application of a dielectric layer 15 of more limited extension reduces the mechanical stresses exerted on the substrate 5.

Such a structuration is achieved by photolithography, for example during the photolithography step resulting in the making of the interconnection aperture 30.

### Second Embodiment

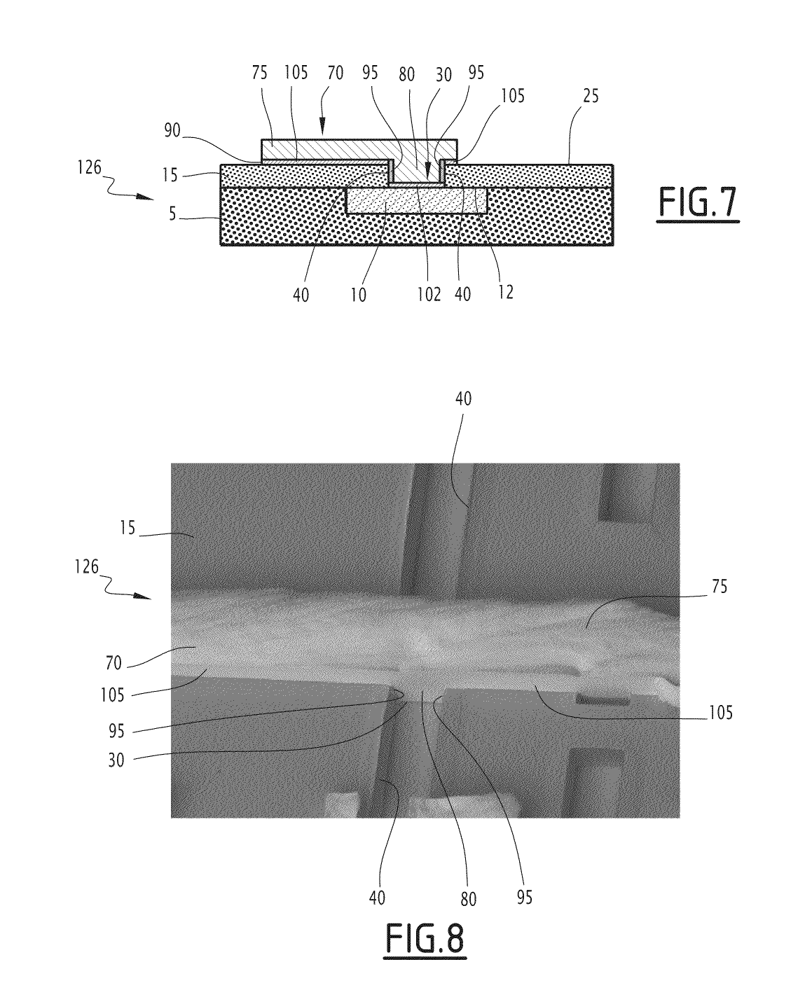

FIG. 9 illustrates a cross-sectional view of a monolithic integrated circuit obtained by the method according to the second embodiment. The obtained integrated circuit differs from the one obtained with the method according to the first embodiment in that the dielectric layer 15 is without any interconnection aperture 30. In this embodiment, the dielectric layer 15 defines a rib having lateral flanks 40. It extends on the active or conductive area 10 while leaving two regions of the area 10 exposed, vertically below its flanks 40. Each flank 40 has a height of more than 10 μm, in particular more than 50 μm. In the illustrated example, this height is about equal to 80 μm.

The step of forming the electrical structure 70 made in one piece of material comprises:

the deposition of the first metallization coating 90 on the exposed upper surfaces of the substrate 5 and of the dielectric layer 15 in order to form the first portion 102 on the upper surface 12 of the substrate 5, and the second portion 105 on the upper surface 25 of the first dielectric layer 15;

the deposition of the second metallization coating 95 on the flanks 40 of the dielectric layer 15, so as to form the continuous electrolytic growth base 96.

the deposition of the resin layer 100 on the regions of the first portion 102 of the first metallization coating 90 which are not intended to be covered with the electrical structure 70;

the electrolytic deposition of the electrical structure 70;

the removal of the resin layer 100; and

the etching of the first metallization coating 90 in the regions in which it is not covered with the electrical structure 70.

During the electrolytic deposition step, an electrical structure 70 made in one piece of material is obtained, comprising the structural element 75 extending on the dielectric layer 15, two interconnection elements 80 each extending along a flank 40 from the structural element 75 and as far as the upper surface 12 of the substrate 5. It further comprises, for each interconnection element 80, a structural element 76 extending on the upper surface 12 of the substrate 5 in register with both exposed regions of the area 10, from the corresponding interconnection element 80. The structural element 75, the interconnection element 80 and the structural elements 76 are simultaneously formed by electrolytic deposition. The structural elements 75 and 76 for example have a thickness comprised between 5 and 200 μm.

### Third Embodiment

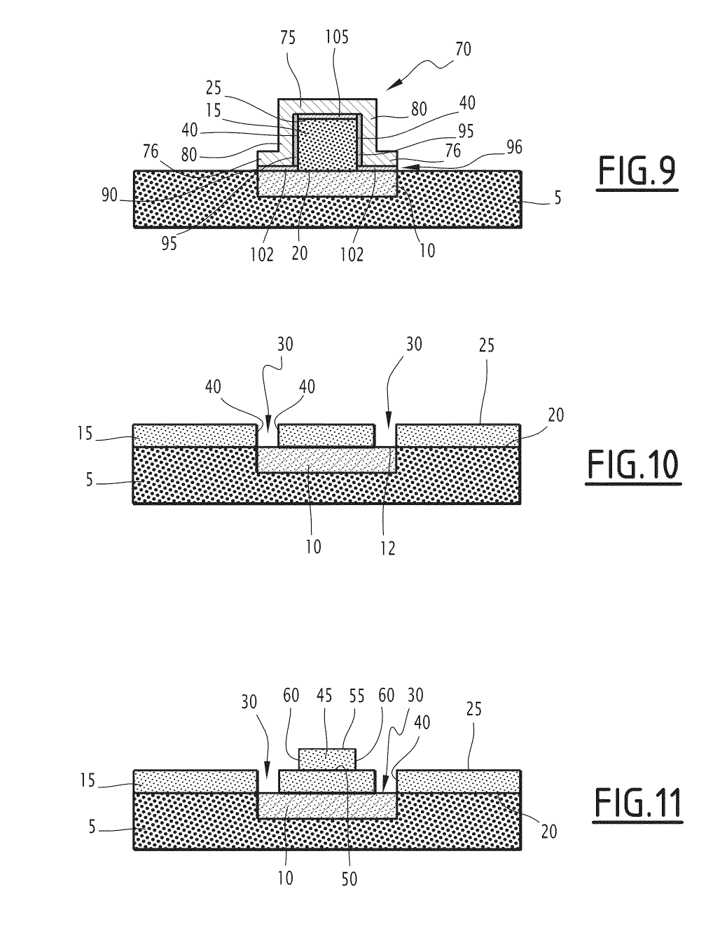

FIGS. 10 to 19 illustrate a monolithic integrated circuit 125 obtained by the method according to the third embodiment. This method differs from the method according to the first embodiment in that an electrical structure with several levels is formed. To do this, a second dielectric layer 45 superposed to the dielectric layer 15 is formed (FIG. 11), which will be described as a first dielectric layer in this embodiment.

The second dielectric layer 45 is formed immediately after the step of forming the first dielectric layer 15 (FIG. 10). The second dielectric layer 45 only partly covers the first dielectric layer 15. Thus, the second dielectric layer 45 leaves exposed regions of the first dielectric layer 15. The particular structure of the second dielectric layer 45 is obtained in a known way, by photolithography.

Both layers 15, 45 form together a dielectric structure. The first dielectric layer comprises two interconnection apertures 30 each delimited by two facing flanks 40 of the first dielectric layer 15. Each interconnection aperture 30 is positioned in register with the active or conducting area 10 and opens into the latter. The second dielectric layer 45 is positioned between the interconnection apertures 30. The dielectric structure formed by the first and the second dielectric layer 15, 45 is stepped.

The second dielectric layer 45 comprises a lower surface 50, an upper surface 55 and at least one flank 60 extending between the upper surface 55 and the upper surface of the underlying dielectric layer, i.e. of the first dielectric layer 15. Each flank 60 has a height of more than 10 μm, in particular more than 25 μm.

In this embodiment, each flank 60 has a height about equal to 50 μm, and each flank 40 of the first dielectric layer 45 has a height about equal to 30 μm. The dielectric structure thus has in every point a height of more than 10 μm, and in the area in which the first and the second dielectric layers 15, 45 are superposed, a height of about equal to 80 μm.

In the illustrated embodiment, each flank 60 is substantially normal to the upper surface 55 of the second dielectric layer 45 and to the upper surface 12 of the substrate 5. According to an alternative, each flank 60 forms an acute angle with the upper surface 12 of the substrate 5.

The second dielectric layer 45 is formed in a polymeric material having the same properties as the material of the first dielectric layer 15, for example in the same material. It is advantageously made in Su-8 polymer.

The step of forming the electrical structure 70 comprises:

the deposition (FIG. 12) of the first metallization coating 90 on the exposed upper surfaces of the substrate 5, of the first dielectric layer 15, and of the second dielectric layer 45 so as to form the first portion 102 on the upper surface 12 of the substrate 5 through the interconnection apertures 30, the second portion 105 on the exposed upper surface 25 of the first dielectric layer 15, and a third portion 110 on the upper surface 55 of the second dielectric layer 45;

the deposition (FIG. 13) of the second metallization coating 95 on the flanks 40 of the first dielectric layer 15, and on the flanks 60 of the second dielectric layer 45, so as to form the continuous electrolytic growth base 96.

the deposition (FIG. 14) of the resin layer 100 on the regions of the second portion 105 of the first metallization coating 90 which are not intended to be covered with the electrical structure 70;

the electrolytic deposition (FIG. 15) of the electrical structure 70;

the removal of the resin layer 100 (FIG. 16); and

the etching (FIG. 17) of the first metallization coating 90 in the region in which it is not covered with the electrical structure 70.

These sub-steps of the step of forming the electrical structure 70 made in one piece of material are similar to those described with reference to the first embodiment.

At the end of the electrolytic deposition step, an electrical structure 70 made in one piece of material is obtained (FIG. 15), comprising:

two first structural elements 75 extending on the first dielectric layer 15, on either side of the second dielectric layer 45;

two interconnection elements 80, described as first interconnection elements 80, each extending through one of the interconnection apertures 30 from a first respective structural element 75 and as far as the upper surface 12 of the substrate 5,

a second structural element 85 extending on the second dielectric layer 45, and

two second interconnection elements 87 each extending along a flank 60 of the second dielectric layer 45 from the second structural element 85 as far as the upper surface of the underlying dielectric layer, which in this case is the upper surface 25 of the first dielectric layer.

The second interconnection elements 87 cover the flank 60. They electrically connect together the first and the second structural element 75, 85.

At the end of the etching step (FIG. 17), a monolithic integrated circuit 125 is formed comprising at least one substrate 5 for example made in a semi-conducting material, as well as at least two electric interconnections levels each defined by the upper surface of a dielectric layer, and respectively formed by the first and the second structural element 75, 85. The interconnection levels are electrically connected together through the interconnection elements 87. The first and the second structural element 75, 85 for example form all or part of electronic components, notably passive electronic components, such as inductors. They may also form interconnection lines intended to connect together various active or conductive areas 10 or different regions of a same active or conducting area 10. The thickness of each of the structural elements 75 and 85 varies according to its electronic function. The first and second structural elements 75, 85 for example have thicknesses comprised between 5 and 200 μm.

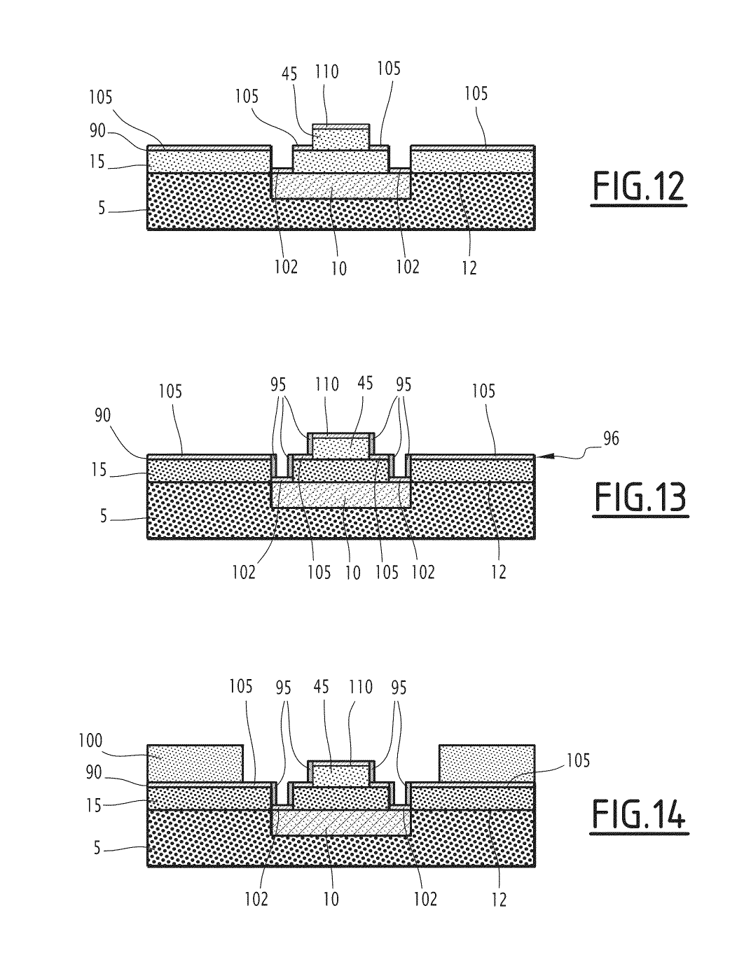

FIG. 18 is a photograph of a cross-section of a portion of the integrated circuit 125, the electrical structure 70 made in one piece of material forming two levels of interconnections above the active area 10 of the substrate 5, and comprising two first interconnection elements 80 making a connection with the active area 10.

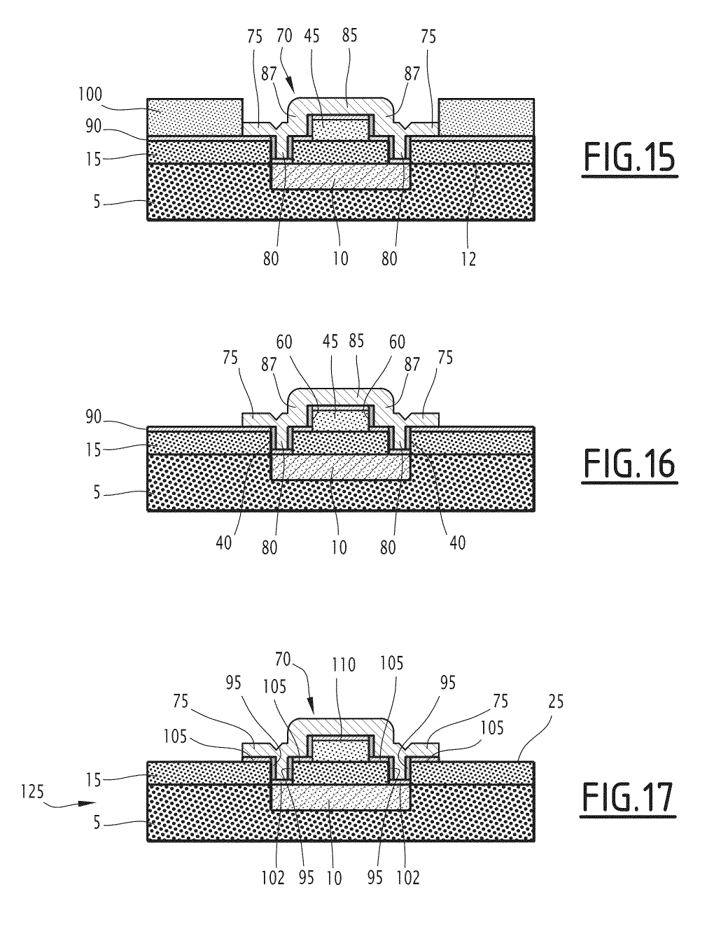

FIG. 19 is a photograph illustrating the integrated circuit 125 obtained with the method according to the invention, the electrical structure 70 forming inductors 127.

### Alternatives

According to an alternative, more than two dielectric layers are superposed. In this case, the manufacturing method comprises, after forming the second dielectric layer 45 and before depositing the first metallization coating 90, intermediate steps of forming additional dielectric layers, each additional dielectric layer being formed over the underlying dielectric layer. Each additional dielectric layer comprises an upper surface, a lower surface and flanks extending between its upper surface and the upper surface of the underlying dielectric layer. According to an embodiment, each dielectric layer has a flank with a height of more than 10 μm.

In this case, the first metal coating 90 is further deposited on the free upper surfaces of each additional dielectric layer and the second metallization coating 95 is further deposited on the flanks of each additional dielectric layer.

The upper surface of each additional dielectric layer defines an interconnection level, the electrical structure comprising a structural element on each of these interconnection levels, as well as for each of these structural elements, an interconnection element extending from the corresponding structural elements and as far as an upper surface of the underlying dielectric layer, so as to connect this structural element to a lower structural element.

The electrical structure 70 made in one piece of material formed in a single electrolytic growth step further comprises the first and second interconnection elements 80, 87 and the first and second structural elements 75, 85, at least one additional structural element extending on one of the additional dielectric layers, in particular on the upper dielectric layer, i.e. the last applied dielectric layer. It further comprises at least one additional interconnection element, extending along the flank of the additional dielectric layer from the additional structural element as far as the upper surface of an underlying dielectric layer. Advantageously, the electrical structure 70 extends on each of the additional dielectric layers. In this case, the electrical structure 70 made in one piece of material that is formed comprises as many interconnection levels as there are dielectric layers.

According to another alternative of the method, according to the first, second and third embodiments according to the invention, one or several intermediate layers, in particular in metal, are interposed between the upper surface 12 of the substrate 5 and the first dielectric layer 15. This or these intermediate layer(s) for example form interconnection layers, to which the electrical structure 70 is connected via the interconnection element 80. In this case, the underlying surface on which the first dielectric layer 15 extends is the upper surface of the intermediate layer immediately underlying the first dielectric layer 15.

According to another alternative, the integrated circuit manufactured by the method according to the invention is a stack of at least two integrated sub-circuits, the electrical structure 70 made in one piece of material notably allowing the sub-circuits to be connected together within the stack.

### ADVANTAGES OF THE INVENTION

The method according to the invention gives the possibility of obtaining, with a reduced number of technological steps, a monolithic circuit integrating passive structures, made on a thick layer of dielectric insulating material, having very good electrical properties, in particular inductors with low losses and a good quality factor. These good electrical properties stem in particular from the use of thick layers of electrical insulator which it is possible to implement on a metal plane producing an electric screen of the substrate.

The significant reduction in the number of steps as compared with traditional methods notably comes from the fact that it allows formation of an electrical structure extending on several levels in a single deposition step by electrolysis, even when the dielectric layer to be stepped across is of a large thickness. Thus, this method does not require that a deposition of an adhesion layer and of a resin be carried out for each interconnection level. Further, as the dielectric layer is formed before the deposition of the electric structure, there are no obstacles during the coating of this layer, so that it is possible to directly obtain a substantially planar upper surface without it being necessary to carry out additional polishing operations.

The use of this technology therefore results in an increase in the manufacturing yields and a significant reduction in the costs.

The deposition in a single step of the electrical structure, including one or several interconnection levels, stretching across thick dielectric layers is made possible by producing the second metallization coating on the flanks of the dielectric layers which allows obtaining a continuous electrolytic growth base over several levels. It is therefore no longer necessary to deposit an adhesion layer and a resin layer for each interconnection level to be made, before proceeding with electrolytic deposition of this interconnection level. The manufacturing method is thus simplified. The method according to the invention has a particular benefit when dielectric resins with straight flanks are used, i.e. forming upon their structuration, flanks perpendicular to the upper surface of the dielectric layer.

The electrical structure 70 formed is a structure made in one piece of material, i.e. it results from a single electrolytic growth step. Consequently, it does not comprise any joints between its different portions, which may weaken it and influence its electrical properties. In particular it is entirely formed in copper, and does not comprise any inserts made in different electrically conducting materials. Thus, its mechanical strength is improved.

By using insulating dielectric layers of a large thickness optionally deposited on a metal screening plane at the surface of the substrate, the passive structures integrated by this method are not or not very sensitive to the low resistivity of the substrate, and their electrical performances are improved.

With the method according to the invention, it is thus possible to manufacture integrated circuits, comprising electrical structures, forming passive structures, in particular interconnections and inductors with very low losses. It gives the possibility of designing and making RF and microwave power amplifiers with high power yield and therefore having reduced consumption. It may also allow implementation of an antenna directly on the integrated circuit.

The use of a high resolution resin gives the possibility of obtaining patterns with a small width with high resin layer thicknesses and widens the field of application of the method, while providing a larger degree of freedom as regards design of components.

Finally, the structuration of the insulating dielectric layer gives the possibility of obtaining passive electric structures which are robust from a mechanical point of view, which have good electrical performances, in particular with low losses.

The use of this technology is not limited to semi-conducting substrates, it may be applied to other types of substrates such as glasses, flexible substrates (PET, polyimide . . . ).

The invention also relates to an integrated circuit obtained according to the method of the invention.

In the first, second and third embodiments and alternatives, the flanks 40 and/or 60 for example have a thickness comprised between 10 μm and 500 μm.

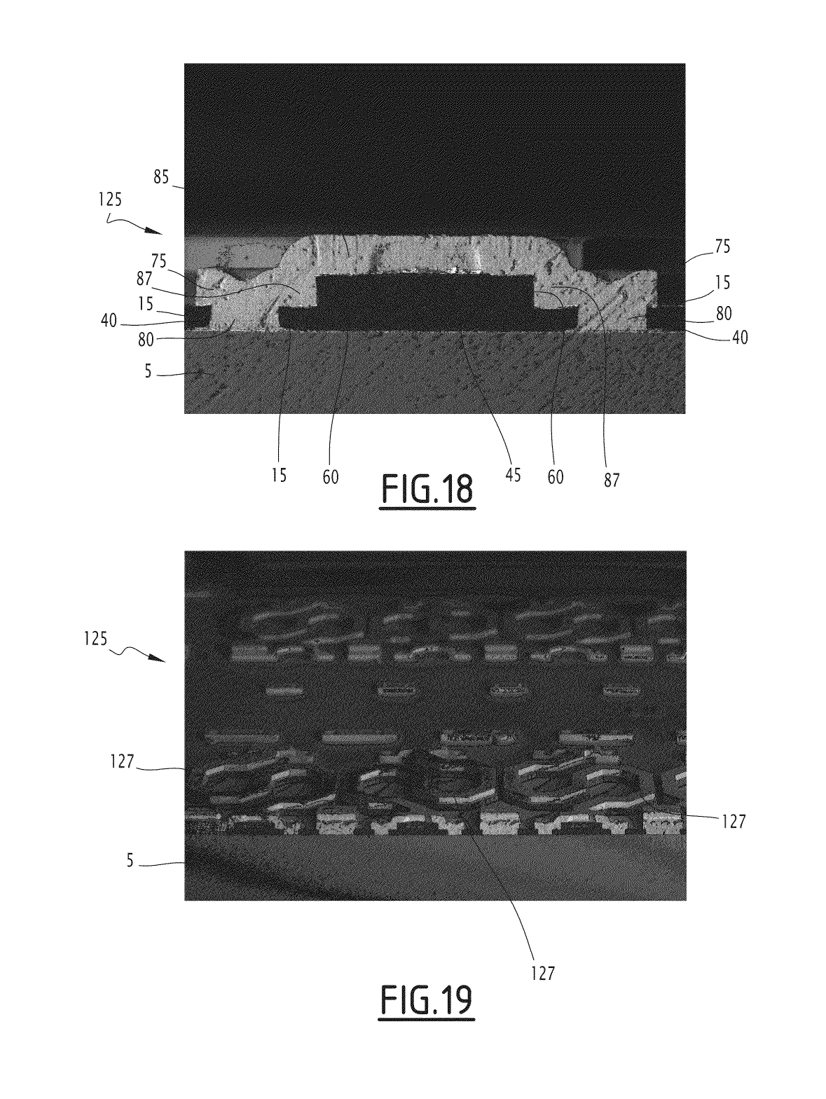

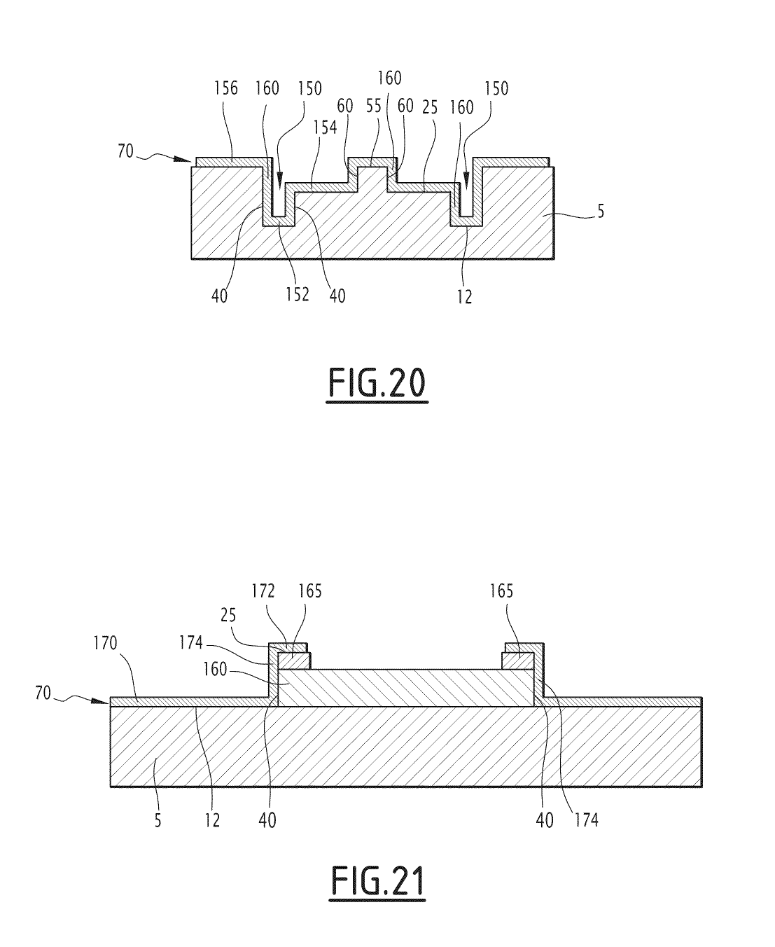

FIGS. 20 and 21 illustrate circuits obtained by methods according to alternatives. The numerical references of the elements similar to those of the first and second embodiments have been preserved.

The circuit illustrated in FIG. 20 differs from the one according to the first and second embodiments in that the electrical structure 70 is not formed on a dielectric layer. According to this alternative, a machined substrate 5 is provided in a first step. The substrate 5 is for example a silicon substrate. It is machined so as to have a first surface 12 and a second surface 25 substantially parallel with each other. The first and second surfaces 12, 25 are spaced apart from each other along the direction normal to the surfaces 12, 25. A flank 40 extends between the first surface 12 and the second surface 25. In the illustrated embodiment, the flanks 40 are substantially normal to the first surface 12.

In the illustrated example, the substrate 5 comprises flanks 40 substantially parallel with each other each extending upwards from a same surface, for example from the first surface 12. These flanks 40 delimit with the portion of the first surface 12 located between the parallel flanks 40, a well 150 in the substrate 5.

In the example illustrated in FIG. 20, the substrate 5 further comprises an additional surface 55 substantially parallel to the first and second surfaces 12, 25. The additional surface 55 is spaced apart from the second surface 25 along the direction normal to this surface. A flank 60 extends between the additional surface 55 and the second surface 25.

According to an embodiment, the flanks 40 and/or 60 have a thickness comprised between 10 μm and 500 μm.

The method for manufacturing the circuit on the machined substrate 5 is similar to the method described with reference to the first and second embodiments, but does not comprise any step of forming a dielectric layer. The first metallization coating is directly formed on the first and second surfaces 12, 25 and optionally on the additional surface 55 of the substrate 5 and the second metallization coating is formed over the flanks 40, 60 of the substrate 5 in order to form the continuous electrolytic growth base 96.

At the end of this method, a circuit is obtained, comprising an electrical structure 70 made in one piece of material, i.e. formed in a single deposition step by electrolysis. This electrical structure 70 made in one piece of material comprises structural elements 152, 154, 156 respectively extending on the first surface 12, the second surface 25 and the additional surface 55 of the substrate 5 and interconnection elements 160, extending along the flanks 40, 60 between the structural elements 152, 154 and 156.

Such a circuit is notably used for microfluidic applications.

The circuit illustrated in FIG. 21 differs from the circuit according to the first and second embodiments in that the electrical structure 70 is not formed on a dielectric layer. According to this alternative, a substrate 5 is provided in a first step, comprising a chip 160 added onto the upper surface 12 of the substrate 5, for example by adhesive bonding. The chip 160 has an upper surface 25 and flanks 40 extending between the upper surface 25 and the upper surface 12 of the substrate 5. The chip 160 comprises on its upper face 25, connection pads 165.

As an option, an intermediate layer is inserted between the chip and the substrate 5. In this case, the flanks 40 extend between the upper surface 25 of the chip 160 and the upper surface of the underlying layer.

In the illustrated embodiment, the flanks 40 are substantially normal to the upper surface 12 of the substrate 5.

According to an embodiment, the flanks 40 have a thickness comprised between 10 pm and 500 μm.

The method for manufacturing the circuit on the substrate 5 provided with the chip 160 is similar to the method described with reference to the first and second embodiments but does not comprise the step of forming a dielectric layer. The first metallization coating 90 is formed on the upper surface 12 of the substrate 5 (optionally on the upper surface of the underlying layer) and on the upper surface 25 of the chip 160. The second metallization coating 95 is formed on at least one flank 40 so as to form the continuous electrolytic growth base 96 with the first metallization coating 90.

The electrical structure 70 made in one piece of material formed at the end of the method comprises at least one first structural element 170 extending on the upper surface 12 of the substrate 5 and a second structural element 172 extending on the upper surface 25 of the chip 160. It further comprises an interconnection element 174 extending between the first structural element 170 and the second structural element 172 so as to electrically connect them together.

Such a circuit for example gives the possibility of electrically connecting together several chips 160 added onto the substrate 5.

In a more general way, the invention relates to a method for manufacturing a circuit, of the type comprising the steps of:

providing an assembly comprising a first surface and a second surface substantially parallel with each other and a flank extending between the first surface and the second surface,

forming electrical structure made in one piece in an electrically conducting material, comprising a structural element extending on the second surface and an interconnection element extending from the structural element along the flank as far as the first surface,

wherein the flank has a height of more than 10 μm, and the electrical structure is formed by depositing the electrically conducting material while simultaneously depositing the structural element on the second upper surface of the dielectric layer and the interconnection element on the flank.

The first and second surfaces are spaced apart along the direction normal to the first and second surfaces.

According to an alternative, the assembly further comprises at least one additional surface substantially parallel to the first and second surfaces, a flank extending between the first surface and the second surface and a flank extending between the second surface and the additional surface, and at least one of the flanks having a height of more than 10 μm,

and wherein the electrical structure is formed by simultaneously depositing a structural element extending on the second surface and a structural element extending on the additional surface and an interconnection element extending along the flanks from the structural element extending on the third surface and/or the second surface as far as the second surface or the first surface respectively.

1. A method for manufacturing a circuit, of the type comprising the steps of:
providing an assembly comprising a first surface (12) and a second surface (25) substantially parallel with each other and a flank (40) extending between the first surface (12) and the second surface (25),
forming an electrical structure (70) made in one piece in an electrically conducting material, comprising a structural element (75) extending on the second surface (25) and an interconnection element (80) extending from the structural element (75) along the flank (40) as far as the first surface (12),
wherein the flank (40) has a height of more than 10 μm, and the electrical structure (70) is formed by depositing the electrically conducting material by simultaneously depositing the structural element (75) on the second surface (25) and the interconnection element (80) on the flank (40).

2. The method according to claim 1, wherein the flank (40) is undercut relatively to the first surface (12) or normal to the first surface (12).

3. The method according to claim 1, wherein the step of forming the electrical structure (70) successively comprises:
the deposition of a first metallization coating (90) on the first surface (12) and on the second surface (25);
the deposition of a second metallization coating (95) on the flank (40); and
the deposition of the electrical structure (70) by electrolytic growth, simultaneously on the first metallization coating (90) and the second metallization coating (95).

4. The method according to claim 3, wherein the deposition of the second metallization coating (95) is achieved by chemical treatment of the flank (40).

5. The method according to claim 3, wherein the step of forming the electrical structure (70) comprises, after the depositions of the first and second metallization coatings (90, 95), the deposition of a resin layer (100) leaving exposed the regions of the first metallization coating (90) intended to be covered with the electrical structure (70) during the electrolytic deposition step, and the removal of the resin layer (100) after the electrolytic deposition.

6. The method according to claim 1, which is a method for manufacturing an integrated circuit, and wherein the step of providing the assembly comprises the step of forming above an upper surface of a substrate (5), at least one dielectric layer (15) extending on an underlying surface (12) forming the first surface of the assembly, the dielectric layer (15) having an upper surface (25) forming the second surface of the assembly and a flank (40) extending between the upper surface (25) of the dielectric layer (15) and the underlying surface (12).

7. The method according to claim 6, wherein the or each dielectric layer (15) is in polymeric material.

8. The method according to claim 6, wherein the flank (40) is undercut relatively to the underlying surface (12) or normal to the underlying surface (12).

9. The method according to claim 6, wherein at least one dielectric layer (15) is provided with an interconnection through-aperture (30) delimited by the flank (40).

10. The method according to claim 1, wherein the assembly further comprises at least one additional surface (55) substantially parallel to the first (12) and second surfaces (25), a flank (40) extending between the first surface (12) and the second surface (40) and a flank (60) extending between the second surface (25) and the additional surface (55), and at least one of the flanks (40, 60) having a height of more than 10 μm,
and wherein the electrical structure (70) is formed by simultaneously depositing a structural element (75) extending on the second surface (25) and a structural element (85) extending on the additional surface (55) and an interconnection element (80, 86) extending along the flanks (40, 60) from the structural element (75, 85) extending on the additional surface (55) and/or on the second surface (25) as far as the second surface (25) or the first surface (12), respectively.

11. The method according to claim 10, wherein each flank (40, 60) has a height of more than 10 μm.

12. The method according to claim 10, wherein the step of depositing the first metallization coating comprises the deposition of the first metallization coating (90) on the additional surface (55) and the step of depositing the second metallization coating comprises the deposition of the second metallization coating (95) on the flank (60).

13. The method according to claim 1, wherein several superposed dielectric layers (15, 45) defining a stepped dielectric structure are formed on the underlying surface (12),
each dielectric layer (15, 45) having an upper surface (25, 55) and a flank (40,60) extending between its upper face (25, 55) and the upper surface (25) of an underlying dielectric layer (15) or the underlying surface (12), at least one of the flanks (40, 60) having a height of more than 10 μm,
and wherein the electrical structure (70) is formed by simultaneously depositing a structural element (75, 85) extending on the upper surface (25, 55) of each dielectric layer (15, 45) and an interconnection element (80, 86) extending along the flank (40, 60) of each dielectric layer (15, 45) from the structural element (75, 85) extending on the upper surface (25, 55) of this dielectric layer (15, 45) as far as the upper surface (25) of the underlying dielectric layer (15) or as far as the underlying surface (12).

14. The method according to claim 13, wherein the flank (40, 60) of each dielectric layer (15, 45) has a height of more than 10 μm.

15. The method according to claim 13, wherein each dielectric layer (15, 45) is in polymeric material.

16. The method according to claim 1, wherein the electrical structure (70) is formed by electrolytic deposition.

17. A circuit comprising an assembly having a first surface (12) and a second surface (25) substantially parallel with each other and a flank (40) extending between the first surface (12) and the second surface (25), an electrical structure (70) made in one piece in an electrically conducting material, comprising a structural element (75) extending on the second surface (25) and an interconnection element (80) extending from the structural element (75) along the flank (40) as far as the first surface (12), wherein the flank (40) has a height of more than 10 μm, and the electrical structure (70) is deposited on the second surface (25) and the interconnection element (80) on the flank (40).

18. The circuit according to claim 17, comprising a substrate (5) having an upper surface, at least one dielectric layer (15) formed above the upper surface of the substrate and extending on an underlying surface (12), the dielectric layer (15) having an upper surface (25) and a flank (40) extending between the upper surface (25) and the underlying surface (12), an electrical structure (70) made in one piece in an electrically conducting material, comprising a structural element (75) extending on the upper surface (25) of the dielectric layer (15) and an interconnection element (80) extending from the structural element (75) along the flank (40) as far as the underlying surface (12), wherein the flank (40) has a height of more than 10 μm, and the electrical structure (70) is deposited on the upper surface (25) and the flank (40) of the dielectric layer (15).

19. The circuit according to claim 17, which comprises a substrate (5) and wherein the first and second surfaces (12, 25) are delimited by the substrate (5).

20. The circuit according to claim 17, which comprises a substrate (5) and a chip (160) added onto the substrate (5) and wherein the first surface (12) is delimited by the substrate (5) and the second surface (25) is delimited by the chip (160).
